(19) United States
(12) Patent Application Publication
(10) Pub. No.: US 2014/0182899 A1
(43) Pub. Date: Jul. 3, 2014

(54) RIGID-FLEXIBLE PRINTED CIRCUIT BOARD AND METHOD FOR MANUFACTURING SAME

(71) Applicants: ZHEN DING TECHNOLOGY CO., LTD., Tayuan (TW); FUKUI PRECISION COMPONENT (SHENZHEN) CO., LTD., Shenzhen (CN)

(72) Inventor: BIAO LI, Shenzhen (CN)

(73) Assignees: ZHEN DING TECHNOLOGY CO., LTD., Tayuan (TW); FUKUI PRECISION COMPONENT (SHENZHEN) CO., LTD., Shenzhen (CN)

(21) Appl. No.: 14/133,464

(22) Filed: Dec. 18, 2013

(30) Foreign Application Priority Data
Dec. 28, 2012 (CN) 2012105823241

(51) Int. Cl. H05K 3/46; H05K 1/02

(52) U.S. Cl. CPC H05K 3/4626; H05K 1/0283
USPC 174/254; 156/268; 156/92

(57) ABSTRACT

A rigid-flexible printed circuit board includes a first circuit substrate, a third circuit substrate, and an adhesive sheet sandwiched between the first circuit substrate and the third circuit substrate. The first circuit substrate is a rigid circuit substrate. The third circuit substrate is a flexible circuit substrate, and includes an exposed area and two lamination areas. The exposed area is sandwiched between the two lamination areas. The first circuit substrate and the adhesive sheet are only laminated onto the two lamination areas. A dielectric layer of the first circuit substrate is a rigid epoxy glass cloth laminate, and a dielectric layer of the third circuit substrate is a flexible epoxy glass cloth laminate.

### BACKGROUND

1. Technical Field

The present disclosure generally relates to printed circuit boards (PCBs), and particularly, relates to a method for making a rigid-flexible printed circuit board, and a rigid-flexible printed circuit board made by the method.

2. Description of Related Art

Rigid-flexible printed circuit boards (R-F PCBs) are widely used in electronic devices. The R-F PCB has a rigid portion and a flexible portion.

The rigid portion is configured for assembling electronic components and maintaining electrical connections among the electronic components. The flexible portion is connected to the rigid portion and can be bent relative to the rigid portion. Thus, a large number of electronic components can be assembled on the rigid portion of the rigid flexible printed circuit board without occupying a large amount of space.

A typical method for manufacturing an R-F PCB is described as follows. First, a flexible printed circuit board (FPCB) is manufactured. Second, a rigid printed circuit board (R-PCB) is laminated on the FPCB, and copper conductive tracks are formed on the R-PCB. Third, an opening is formed in a region of the R-PCB for exposing part of the FPCB, thereby forming a flexible portion. Other parts of the FPCB and the corresponding R-PCB form a rigid portion. Thus, an R-F PCB having a flexible portion and a rigid portion is obtained. Before forming the R-PCB, a coating layer and a peelable binder layer is sequentially laminated on the FPCB in the flexible portion. Sometimes, an electro-magnetic shielding layer and another coating layer are formed between the coating layer and the peelable binder layer in the flexible portion. When the R-PCB is laminated on the FPCB, these additional layers in the flexible portion will cause the thickness of the flexible portion to be much greater than that of the rigid portion. However, in the method for making the R-F PCB, because there are many laminations, there is a longer process to making the R-F PCB. This will reduce the productivity of the R-F PCB. In addition, because a thermal expansion coefficient of the flexible portion is far away from a thermal expansion coefficient of the rigid portion, it is difficult for controlling expansion and shrinkage of the flexible portion and the rigid portion. This will reduce the quality of the R-F PCB.

What is needed, therefore, is a method for manufacturing a rigid-flexible printed circuit board and a rigid-flexible printed circuit board with an embedded component to overcome the above-described problems.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 shows a first circuit substrate, a second circuit substrate, a third circuit substrate, a first adhesive sheet, and a second adhesive sheet according to an exemplary embodiment.

FIG. 2 shows a multilayer substrate obtained by laminating the first circuit substrate, the second circuit substrate, the third circuit substrate, the first adhesive sheet, and the second adhesive sheet of FIG. 1 onto each other.

FIG. 3 shows a fifth wiring layer and a sixth wiring layer formed on the multilayer substrate of FIG. 2.

FIG. 4 shows a first solder mask formed on the fifth wiring layer, and a second solder mask on the sixth wiring layer of FIG. 3.

FIG. 5 shows a rigid-flexible printed circuit board according to the exemplary embodiment.

### DETAILED DESCRIPTION

Embodiments will now be described in detail with reference to the drawings.

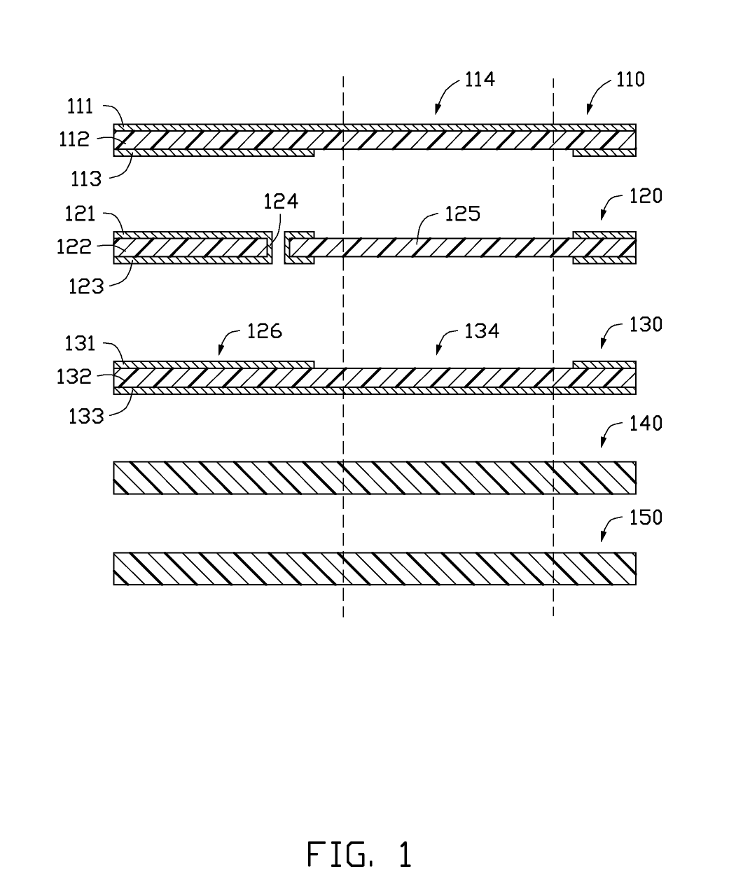

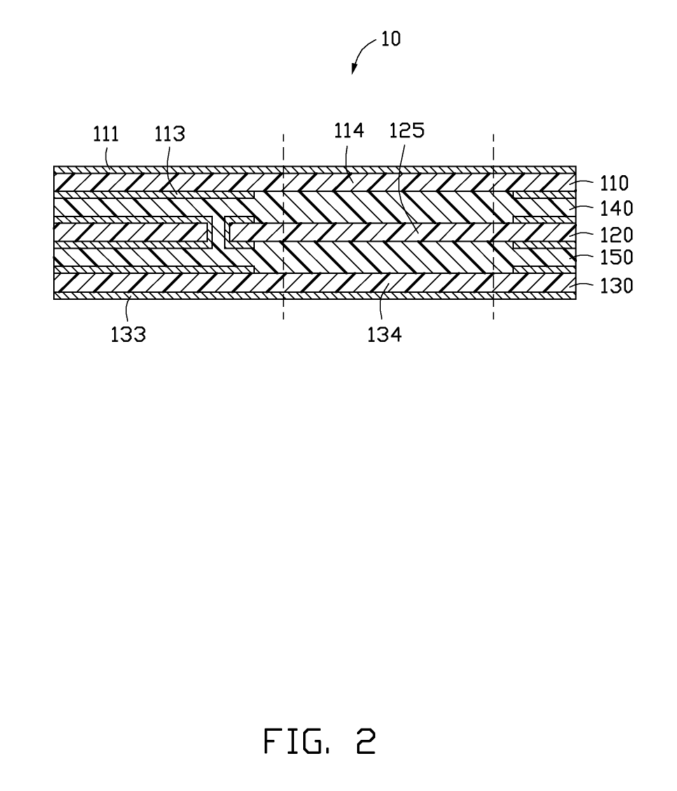

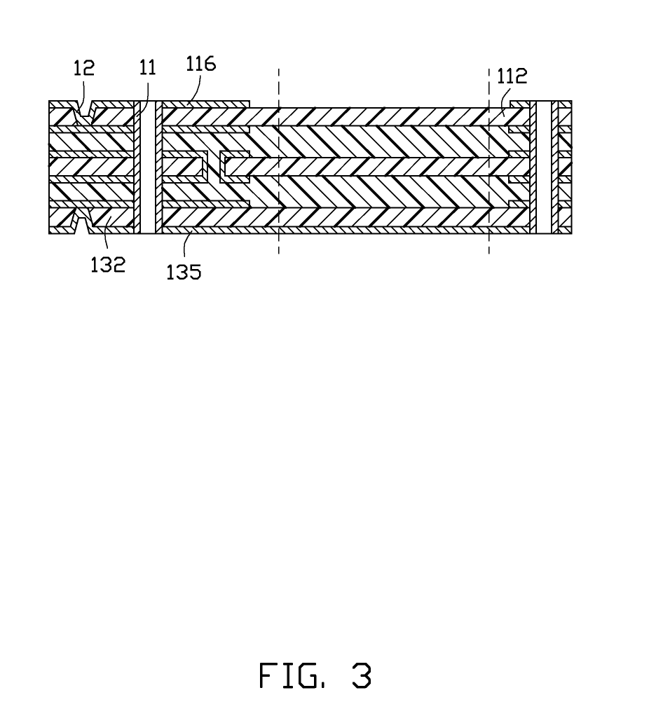

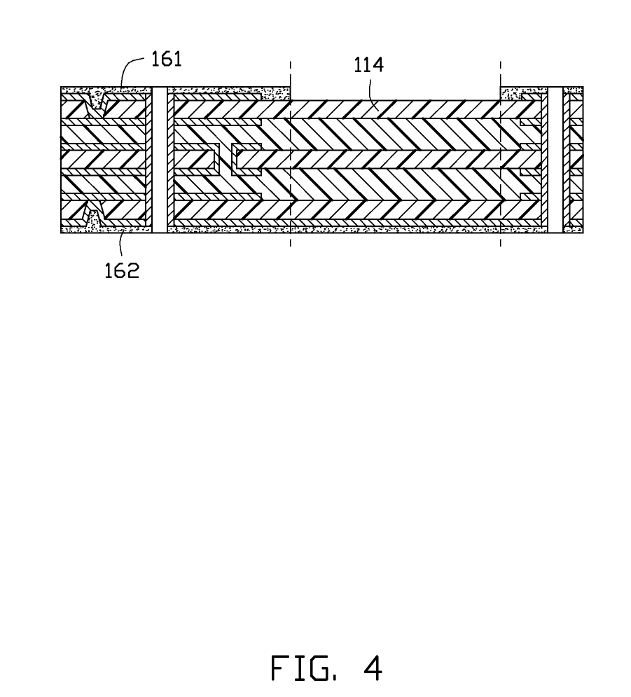

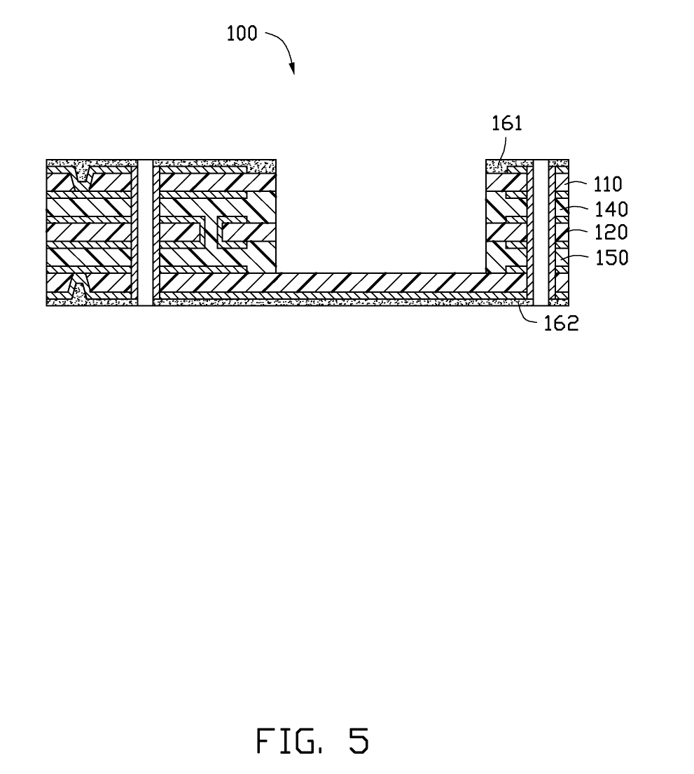

FIGS. 1-5 show that a method for manufacturing a rigid-flexible printed circuit board (R-F PCB) according to an exemplary embodiment includes the following steps.

In step 1, a first circuit substrate 110, a second circuit substrate 120, a third circuit substrate 130, a first adhesive sheet 140, and a second adhesive sheet 150 are provided.

The first circuit substrate 110 and the second circuit substrate 120 are rigid circuit substrate, and the third circuit substrate 130 is a flexible circuit substrate.

The first circuit substrate 110 includes a first copper layer 111, a first dielectric layer 112, and a first wiring layer 113. The first dielectric layer 112 is made of a rigid epoxy glass cloth laminate. The first copper layer 111 is formed on a surface of the first dielectric layer 112. The first wiring layer 113 is formed on the other surface of the dielectric layer 112. The first circuit substrate 110 includes a first removable area 114. In the first removable area 114, there is no wire at the first wiring layer 113.

The second circuit substrate 120 includes a second wiring layer 121, a second dielectric layer 122, and a third wiring layer 123. The second dielectric layer 122 is made of a rigid epoxy glass cloth laminate. The second dielectric layer 122 is sandwiched between the second wiring layer 121 and the third wiring layer 123. In the present embodiment, there is a first conductive via 124 formed in the second circuit substrate 120. The first conductive via 124 passes through the second dielectric layer 122. The second wiring layer 121 is electrically connected to the third wiring layer 123 by the first conductive via 124. The second circuit substrate 120 includes a second removable area 125 spatially corresponding to the first removable area 114. In the second removable area 125, there is no wire at the second wiring layer 121 and the third wiring layer 123.

The third circuit substrate 130 includes a fourth wiring layer 131, a third dielectric layer 132, and a second copper foil layer 133. The third dielectric layer 132 is made of a rigid epoxy glass cloth laminate. The third dielectric layer 132 is sandwiched between the fourth wiring layer 131 and the second copper foil layer 133. The third circuit substrate 130 includes an exposed area 134 spatially corresponding to the first removable area 114, and two lamination areas 134. The exposed area 134 is sandwiched between the two lamination areas 134. In the exposed area 134, there is no wire at the fourth wiring layer 131.

In the present embodiment, because the first dielectric layer 112, the second dielectric layer 122, and the third dielectric layer 132 are made of epoxy glass cloth laminates, the thermal expansion coefficients of the first dielectric layer 112, the second dielectric layer 122, and the third dielectric layer 132 are similar to each other. A thickness of the third dielectric layer 132 is in a range from 50 micrometers to 70 micrometers.

The first adhesive sheet 140 and the second adhesive sheet 150 are preprges.

In step 2 the first circuit substrate 110, the first adhesive sheet 140, the second circuit substrate 120, the second adhesive sheet 150, and the third circuit substrate 130 are stacked in a described order, such that the first removable area 114, the second removable area 125, and the exposed area 134 corresponds to each other, and are laminated onto each other to obtain a multilayer substrate 10.

When stacking, the first wiring layer 113 is adjacent to the first adhesive sheet 140; the fourth wiring layer 131 is adjacent to the second adhesive sheet 150; the first copper foil layer 111 is at a side surface of the multilayer substrate 10, and the second foil layer 133 is at the other side surface of the multilayer substrate 10.

Before lamination, the first circuit substrate 110, the first adhesive sheet 140, the second circuit substrate 120, the second adhesive sheet 150, and the third circuit substrate 130 may be processed by a hot riveting, such that the first circuit substrate 110, the second circuit substrate 120, and the third circuit substrate 130 are exactly aligned.

In step 3, the first copper foil layer 111 is converted into a fifth wiring layer 116, and the second copper foil layer 133 is converted into a sixth wiring layer 135. The fifth wiring layer 116 and the sixth wiring layer 135 are outer wiring layers.

Before forming the fifth wiring layer 116 and the sixth wiring layer 135, a number of plated through vias 11 and conductive blind vias 12 are formed in the multilayer substrate 11.

In the present embodiment, the fifth wiring layer 116 and the sixth wiring layer 135 are formed by an image transfer process and an etching process. In the first removable area 114, there is no wire in the fifth wiring layer 116. A wire of the sixth wiring layer 135 extends from an end of the exposed area 134 to the other end of the exposed area 134, such that wires at two end of the exposed area 134 can be electrically connected to each other. The fourth wiring layer 131 is electrically connected to the sixth wiring layer 135 by the conductive blind via 12. The fifth wiring layer 116 is electrically connected to the first wiring layer 111 by the conductive blind via 12. The fifth wiring layer 116 is electrically connected to the sixth wiring layer 135 by the plated through via 11.

In step 4, a first solder mask 161 is formed on a surface of the fifth wiring layer 116, and a second solder mask 162 is formed on a surface of the sixth wiring layer 135. In this step, the first solder mask 161 and the second solder mask 162 are formed by printing an ink. In the present embodiment, there is no first solder mask 161 at a position of the fifth wiring layer 161 spatially corresponding to the first removable area 114.

In step 5, the first removable area 114, the second removable area 125, a portion of the first adhesive sheet 140 between the first removable area 114 and the second removable area 125, and a portion of the second adhesive sheet 150 between the second removable area 125 and the exposed area 135 are removed from the multilayer substrate 10 by a routing process, thereby obtaining a rigid-flexible printed circuit board 100.

In this step, the routing process may be processed by a routing machine with higher depth accuracy, for example a routing machine with plus-minus 30 micrometers, to remove the first removable area 114, the second removable area 125, the portion of the first adhesive sheet 140 between the first removable area 114 and the second removable area 125, and the portion of the second adhesive sheet 150 between the second removable area 125 and the exposed area 135 from the multilayer substrate 10, thereby exposing the exposed area 135.

Because the first removable area 114, the second removable area 125, the portion of the first adhesive sheet 140 between the first removable area 114 and the second removable area 125, and the portion of the second adhesive sheet 150 between the second removable area 125 and the exposed area 135 are removed from the multilayer substrate 10, the exposed area 135 is exposed from two sides of the rigid-flexible printed circuit board 100.

In the method for manufacturing the rigid-flexible printed circuit board 100, there may be two, three, or more second circuit substrates 120 between the first circuit substrate 110 and the third circuit substrate 130, thereby obtaining more multilayer rigid-flexible printed circuit board. In the method for manufacturing the rigid-flexible printed circuit board 100, there may be no second circuit substrate 120 between the first circuit substrate 110 and the third circuit substrate 130, thereby be obtaining a rigid-flexible printed circuit board with fourth wiring layers.

The rigid-flexible printed circuit board 100 includes the first circuit substrate 110, the second circuit substrate 120, the third circuit substrate 130, the first adhesive sheet 140 between the first circuit substrate 110 and the second circuit substrate 120, and the second adhesive sheet 150.

The third circuit substrate 130 includes the exposed area 135 and two lamination areas 136. The exposed area 135 is sandwiched between the two lamination areas 136. The first circuit substrate 110, the second circuit substrate 120, the first adhesive sheet 140, and the second adhesive sheet 150 are only laminated onto the lamination areas 136 of the third circuit substrate 130. The exposed area 135 of the third circuit substrate 130 is exposed to the outside from the two opposite sides of the rigid-flexible printed circuit board 100.

Each of the first circuit substrate 110 and the second circuit substrate 120 includes a rigid dielectric layer and two wiring layers respectively formed at two opposite sides of the rigid dielectric layer. The third circuit substrate 130 includes a flexible dielectric layer and two wiring layers respectively formed at two opposite sides of the flexible dielectric layer. The wiring layer formed on the surface of the flexible dielectric layer adjacent to the adhesive sheet is only formed at the lamination area of the third circuit substrate 130. The rigid dielectric layers of the first circuit substrate 110 and the second circuit substrate 120 are made of rigid epoxy glass cloth laminates. The dielectric layer of the third circuit substrate 130 is made of flexible epoxy glass cloth laminates.

The rigid-flexible printed circuit board 100 also includes the first solder mask 161 and the second solder mask 162 respectively formed at two opposite surfaces of the rigid-flexible printed circuit board 100.

The rigid-flexible printed circuit board 100 may include three or more rigid circuit substrates and adhesive sheets, thereby obtaining a rigid-flexible printed circuit board with seven or more wiring layers. There is no second circuit substrate 120 and the second adhesive sheet 150, thereby obtaining a rigid-flexible printed circuit board with fourth wiring layers.

In the method for manufacturing the rigid-flexible printed circuit board 100, because the lamination is processed between the third circuit substrate being a flexible circuit substrate with dielectric layers similar to the dielectric layer of the first circuit substrate being a rigid circuit substrate and the second circuit substrate being a rigid circuit substrate, there is no need a material of flexible circuit substrate. In addition, the material of the third circuit substrate is similar to the material of the first circuit substrate, and the thermal expansion coefficient of the third circuit substrate is similar to the thermal expansion coefficient of the first circuit substrate. Accordingly, it is easy for controlling expansion and shrinkage of the flexible portion and the rigid portion.

While certain embodiments have been described and exemplified above, various other embodiments will be apparent from the foregoing disclosure to those skilled in the art. The disclosure is not limited to the particular embodiments described and exemplified but is capable of considerable variation and modification without departure from the scope and spirit of the appended claims.

What is claimed is:

1. A method for manufacturing a rigid-flexible printed circuit board, comprising:
providing a first circuit substrate, a third circuit substrate, and an adhesive sheet, the first circuit substrate being a rigid circuit substrate, and comprising a first dielectric layer, and a first copper foil layer formed on the first dielectric layer, the third circuit substrate being a flexible circuit substrate, and comprising a third dielectric layer, and a second copper foil layer formed on the third dielectric layer, the first dielectric layer being made of a rigid epoxy glass cloth laminate, the third dielectric layer being made of a flexible epoxy glass cloth laminate, the third circuit substrate comprising an exposed area, and two lamination areas, the exposed area being sandwiched between the two lamination areas;
stacking and laminating the first circuit substrate, the adhesive sheet, the third circuit substrate onto each other in a described order, thereby obtaining a multilayer substrate, the first copper foil layer being exposed to the outside from one side of the multilayer substrate, and the second copper foil layer being exposed to the outside from the other side of the multilayer substrate;
converting the first copper foil layer and the second copper foil layer to wiring layers, and
removing a portion of the first circuit substrate spatially corresponding to the exposed area, and a portion of the adhesive sheet spatially corresponding to the exposed area from the multilayer substrate, thereby exposing the exposed area to obtaining a rigid-flexible printed circuit board.

2. The method of claim 1, wherein the first circuit substrate further comprises a first wiring layer formed at the other surface of the first dielectric layer, the first circuit substrate comprises a removable area spatially corresponding to the exposed area, and the first wiring layer is formed at an area of the first dielectric layer except for the removable area.

3. The method of claim 1, wherein after stacking the first circuit substrate, the adhesive sheet, and the third circuit substrate onto each other, and before laminating the first circuit substrate, the adhesive sheet, and the third circuit substrate onto each other, the method further comprising a step of hot riveting the first circuit substrate, the adhesive sheet, and the third circuit substrate onto each other.

4. The method of claim 1, wherein the third circuit substrate further comprises a fourth wiring layer formed on the other surface of the third dielectric layer, and the fourth wiring layer is only formed at the lamination areas.

5. The method of claim 1, wherein before the routing process, the method further comprises a step of forming a solder mask on the wiring layer converted by the first copper foil layer.

6. A method for manufacturing a rigid-flexible printed circuit board, comprising:
providing a first circuit substrate, at least one second circuit substrate, a third circuit substrate, and at least two adhesive sheets, the first circuit substrate being a rigid circuit substrate, and comprising a first dielectric layer, and a first copper foil layer formed on the first dielectric layer, the second circuit substrate being a rigid circuit substrate, and comprising a second dielectric layer, and two wiring layers, the second dielectric layer being sandwiched between the two wiring layers of the rigid second circuit substrate, the third circuit substrate being a flexible circuit substrate, and comprising a third dielectric layer, and a second copper foil layer formed on the third dielectric layer, the first dielectric layer and the second dielectric layer being made of a rigid epoxy glass cloth laminates, the third dielectric layer being made of a flexible epoxy glass cloth laminate, the third circuit substrate comprising an exposed area, and two lamination areas, the exposed area being sandwiched between the two lamination areas;
stacking and laminating the first circuit substrate, the at least one second circuit substrate, the at least two adhesive sheets, the third circuit substrate onto each other, such that the at least one second circuit substrate and the at least two adhesive sheets are sandwiched between the first circuit substrate and the third circuit substrate, and each adhesive sheet is sandwiched between the two circuit substrate, thereby obtaining a multilayer substrate, the first copper foil layer being exposed to the outside from one side of the multilayer substrate, and the second copper foil layer being exposed to the outside from the other side of the multilayer substrate;
converting the first copper foil layer and the second copper foil layer to wiring layers, and
removing a portion of the first circuit substrate spatially corresponding to the exposed area, a portion of the at least one second circuit substrate spatially corresponding to the exposed area, and a portion of the adhesive sheet spatially corresponding to the exposed area from the multilayer substrate by a routing process, thereby exposing the exposed area to obtaining a rigid-flexible printed circuit board.

7. The method of claim 6, wherein the second circuit substrate comprises a second removal area spatially corresponding to the exposed area, the wiring layers of the second circuit substrate are formed at an area of the second dielectric layer except for the second removable area.

8. The method of claim 6, wherein after stacking the first circuit substrate, the at least one second circuit substrate, the at least two adhesive sheets, and the third circuit substrate onto each other, and before laminating the first circuit substrate, the at least one second circuit substrate, the at least two adhesive sheets, and the third circuit substrate onto each other, the method further comprising a step of hot riveting the first circuit substrate, the at least one second circuit substrate, the at least two adhesive sheets, and the third circuit substrate, which are stacked onto each other.

9. The method of claim 6, wherein before the routing process, the method further comprises a step of forming a solder mask on the wiring layer converted by the first copper foil layer.

10. A rigid-flexible printed circuit board, comprises a first circuit substrate, a third circuit substrate, and an adhesive sheet sandwiched between the first circuit substrate and the third circuit substrate, the first circuit substrate being a rigid circuit substrate, the third circuit substrate being a flexible circuit substrate, the third circuit substrate comprising an exposed area and two lamination areas, the exposed area being sandwiched between the two lamination areas, the first circuit substrate and the adhesive sheet being only laminated onto the two lamination areas, a dielectric layer of the first circuit substrate being a rigid epoxy glass cloth laminate, and a dielectric layer of the third circuit substrate being a flexible epoxy glass cloth laminate.
